(19) United States
(12) Patent Application Publication
(10) Pub. No.: US 2025/0127067 A1
(43) Pub. Date: Apr. 17, 2025

(54) SEMICONDUCTOR DEVICE AND METHOD FOR FABRICATING THE SAME

(71) Applicant: SK hynix Inc., Icheon-si (KR)

(72) Inventor: Cha Deok DONG, Icheon-si (KR)

(21) Appl. No.: 18/607,280

(22) Filed: Mar. 15, 2024

(30) Foreign Application Priority Data
Oct. 11, 2023 (KR) 10-2023--0135099

(51) Int. Cl. H10N 70/00; H10B 61/00; H10B 63/00; H10N 50/01; H10N 50/10; H10N 50/80

(52) U.S. Cl. CPC H10N 70/841; H10B 61/00; H10B 63/84; H10N 50/01; H10N 50/10; H10N 50/80; H10N 70/021

(57) ABSTRACT

A semiconductor device and a method for fabricating the same are provided. The semiconductor device includes: a selector pattern configured to exhibit different electrical conducting characteristics in response to an applied voltage with respect to a threshold voltage; an interlayer insulating layer surrounding a sidewall of the selector pattern and having an opening disposed over the selector pattern; and an electrode disposed in the opening and having a width that is maximum at an uppermost portion of the opening, and wherein the uppermost portion of the opening has a rounded edge in a cross-sectional view.

### PRIORITY CLAIM AND CROSS-REFERENCE TO RELATED APPLICATION

This patent document claims priority under 35 U.S.C. § 119 to Korean Patent Application No. 10-2023-0135099 filed on Oct. 11, 2023, which is incorporated herein by reference in its entirety.

### TECHNICAL FIELD

This patent document relates to a semiconductor technology, and more particularly a semiconductor device including a selector, and a method for fabricating the same.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include: a selector pattern configured to exhibit different electrical conducting characteristics in response to an applied voltage with respect to a threshold voltage; an interlayer insulating layer surrounding a sidewall of the selector pattern and having an opening disposed over the selector pattern; and an electrode disposed in the opening and having a width that is maximum at an uppermost portion of the opening, and wherein the uppermost portion of the opening has a rounded edge in a cross-sectional view.

In an embodiment, a method for fabricating a semiconductor device, may include: providing a stacked structure in which a selector pattern and a sacrificial electrode are stacked to each other, wherein the selector pattern is configured to exhibit different electrical conducting characteristics in response to an applied voltage with respect to a threshold voltage; forming an interlayer insulating layer surrounding a sidewall of the stacked structure; removing the sacrificial electrode to form an initial opening; expanding a width of an uppermost portion of the initial opening to form an opening; and forming an electrode filled in the opening.

### BRIEF DESCRIPTION OF THE DRAWINGS

FIG. 1 is a perspective view illustrating a semiconductor device according to an embodiment of the present disclosure.

FIGS. 2A to 2F are cross-sectional views illustrating a semiconductor device according to another embodiment of the present disclosure, and a method for fabricating the same.

FIG. 2G is a cross-sectional view illustrating an example of a variable resistance pattern.

FIGS. 3A to 3C are cross-sectional views illustrating a semiconductor device according to another embodiment of the present disclosure, and a method for fabricating the same.

FIGS. 4A to 4C are cross-sectional views illustrating a semiconductor device according to another embodiment of the present disclosure, and a method for fabricating the same.

FIGS. 5A to 5C are cross-sectional views illustrating a semiconductor device according to another embodiment of the present disclosure, and a method for fabricating the same.

FIGS. 6A and 6B are cross-sectional views illustrating a semiconductor device according to another embodiment of the present disclosure, and a method for fabricating the same.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

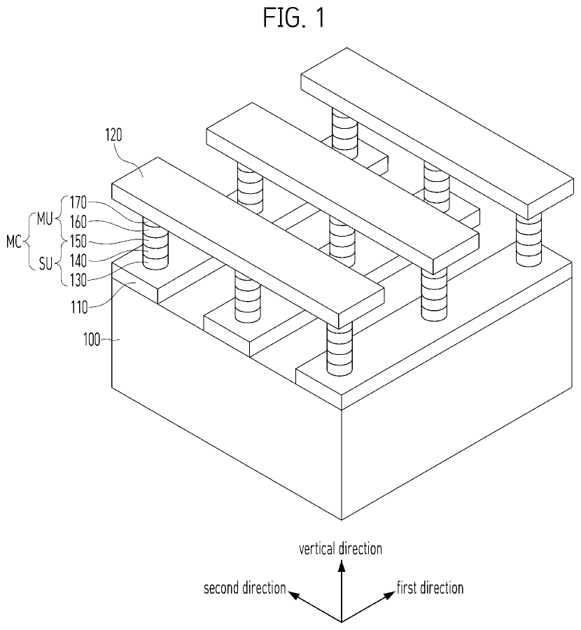

FIG. 1 is a perspective view illustrating a semiconductor device according to an embodiment of the present disclosure.

Referring to FIG. 1, a semiconductor device of the present embodiment may include a substrate 100, a plurality of first conductive lines 110 disposed over the substrate 100 and extending in a first direction, a plurality of second conductive lines 120 disposed over the first conductive lines 110 and extending in a second direction intersecting the first direction, and a plurality of memory cells MC disposed between the first conductive lines 110 and the second conductive lines 120 and respectively overlapping the intersection regions of the first conductive lines 110 and the second conductive lines 120. Here, the first direction and the second direction may correspond to a horizontal direction substantially parallel to the upper surface of the substrate 100. A direction substantially perpendicular to the upper surface of the substrate 100 will hereinafter be referred to as a vertical direction.

The substrate 100 may include a semiconductor material such as silicon. Additionally, a required lower structure (not shown) may be formed in the substrate 100. For example, an integrated circuit for driving the first conductive lines 110 and/or the second conductive lines 120 may be formed in the substrate 100.

The plurality of first conductive lines 110 may be arranged to be spaced apart from each other in the second direction. The first conductive line 110 may include at least one of various conductive materials, for example, a metal such as platinum (Pt), tungsten (W), aluminum (Al), copper (Cu), tantalum (Ta), or titanium (Ti), a metal nitride such as titanium nitride (TIN), tantalum nitride (TaN), or tungsten nitride (WN), or a combination thereof, and may have a single-layer structure or a multi-layer structure.

The plurality of second conductive lines 120 may be arranged to be spaced apart from each other in the first direction. The second conductive line 120 may include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof, and may have a single-layer structure or a multi-layer structure.

Each of the plurality of memory cells MC may include a memory unit MU that is a part where data is actually stored, and a selector unit SU that controls access to the memory unit MU. As an example, the memory cell MC may include a stacked structure of a lower electrode layer 130, a selector layer 140, a middle in 150, a variable resistance layer 160, and an upper electrode layer 170. Here, the selector unit SU may include the lower electrode layer 130, the selector layer 140, and the middle electrode layer 150, and the memory unit MU may include the middle electrode layer 150, the variable resistance layer 160, and the upper electrode layer 170. The middle electrode layer 150 may be shared by the selector unit SU and the memory unit MU.

The lower electrode layer 130 and the upper electrode layer 170 may be located at both ends of the memory cell MC, that is, at the bottom and the top of the memory cell MC, respectively, and may function to transmit a voltage or current necessary for the operation of the memory cell MC. The middle electrode layer 150 may function to physically separate and electrically connect the selector layer 140 and the variable resistance layer 160. The lower electrode layer 130, the middle electrode layer 150, or the upper electrode layer 170 may include at least one of various conductive materials, for example, a metal such as platinum (Pt), tungsten (W), aluminum (Al), copper (Cu), tantalum (Ta), or titanium (Ti), a metal nitride such as titanium nitride (TIN), tantalum nitride (TaN), or tungsten nitride (WN), or a combination thereof. Alternatively, the lower electrode layer 130, the middle electrode layer 150, or the upper electrode layer 170 may include a carbon electrode.

The selector layer 140 may control access to the variable resistance layer 160, and may prevent or reduce current leakage that occurs between the memory cells 120 sharing the first conductive line 110 or the second conductive line 120. The selector layer 140 may have a threshold switching characteristic by exhibiting two different electrical conducting states: a first electrical conducting state in which a current is blocked or hardly flows in the selector layer 140 when the magnitude of the voltage supplied to the selector layer 140 is less than a predetermined threshold voltage, and a second electrical conducting state in which the current rapidly flows through the selector layer 140 at a voltage equal to or higher than the threshold voltage. Thus, the selector layer 140 may be turned on above the threshold voltage and turned off below the threshold voltage. Because the selector layer 140 exhibits different electrical conducting characteristics in response to an applied voltage with respect to a threshold voltage and thus can be controlled via the applied voltage to be selected in one of the two different electrical conducting states, the selector layer 140 functions as a selector for selecting whether the memory cell embodying the selector layer 140 is selected or not.

The selector layer 140 may include a diode, an OTS (Ovonic Threshold Switching) material such as a chalcogenide-based material, an MIEC (Mixed Ionic Electronic Conducting) material such as a metal-containing chalcogenide-based material, an MIT (Metal Insulator Transition) material such as NbO₂ or VO₂, or a tunneling insulating material with a relatively wide band gap, such as SiO₂ or Al₂O₃.

In some implementations, the selector layer 140 may include an insulating material doped with a dopant. Here, the insulating material may include a silicon-containing insulating material such as silicon oxide, silicon nitride, or silicon oxynitride, an insulating metal oxide, an insulating metal nitride, or a combination thereof. The dopant may serve to create trap sites that trap conductive carriers moving within the insulating material and provide a passage for the trapped conductive carriers to move again. To form such trap sites, at least one of various elements capable of generating energy levels for accommodating the conductive carriers within the insulating material may be used as the dopant. As an example, when the insulating material contains silicon, the dopant may include a metal with a different valence than silicon, such as gallium (Ga), boron (B), indium (In), phosphorus (P), arsenic (As), antimony (Sb), germanium (Ge), carbon (C), tungsten (W), or a combination thereof. In some implementations, when the insulating material contains a metal, the dopant may include another metal having a different valence than the metal, or silicon. In an example, the selector layer 140 may include silicon dioxide (SiO₂) doped with arsenic (As). When a voltage equal to or higher than the threshold voltage is applied to the selector layer 140, the conductive carriers move through the trap sites, and thus, an on state may be implemented, in which a current flows through the selector layer 140. When the voltage applied to the selector layer 140 is reduced to less than the threshold voltage, an off state may be implemented, in which the conductive carriers do not move.

The variable resistance layer 160 may be a part that functions to store data in the memory cell MC. In the example, the variable resistance layer 160 may have a variable resistance characteristic that switches between different resistance states depending on an applied voltage thereto. The variable resistance layer 160 may include at least one of various materials used in RRAM, PRAM, FRAM, MRAM, or others, for example, a metal oxide such as a transition metal oxide or a perovskite-based material, a phase change material such as a chalcogenide-based material, a ferroelectric or a ferromagnetic material, and may have a single-layer structure or a multi-layer structure. In an example, the variable resistance layer 160 may include a magnetic tunnel junction structure that can store data by switching between different resistance states by changing the magnetization direction. When the variable resistance layer 160 has a high resistance state, the memory cell MC may store, for example, data ‘0’, and when the variable resistance layer 160 has a low resistance state, the memory cell MC may store, for example, data ‘1’. In some other implementations, the variable resistance layer 160 may store data ‘1’ when the variable resistance layer 160 has a high resistance state and the variable resistance layer may store data ‘0’ when the variable resistance layer 160 has a low resistance state.

This memory cell MC may have a pillar shape that overlaps the intersection region of the first conductive line 110 and the second conductive line 120. In FIG. 1, the memory cell MC is shown as having a cylindrical shape, but the present disclosure is not limited thereto, and the memory cell MC may have at least one of various shapes such as a square pillar shape, a rectangular pillar shape, or an elliptical pillar shape. In addition, in FIG. 1, the layers 130 to 170 for forming the memory cell MC are shown as having sidewalls aligned with each other by being patterned using a single mask, but the present disclosure is not limited thereto. For example, when the variable resistance layer 160 has a multi-layer structure such as a magnetic tunnel junction structure, it may be difficult to collectively etch the layers 130 to 170 for forming the memory cell MC using a single mask. In the example, the layers 130 to 170 may be patterned using multiple masks. For example, the selector layer 140 and the variable resistance layer 160 may be patterned separately using different masks, so they may have sidewalls that are not aligned with each other. In the example, the lower electrode layer 130 may be patterned together with the selector layer 140. In the example, the upper electrode layer 170 may be patterned together with the variable resistance layer 160. In the example, the middle electrode layer 150 may be patterned together with the selector layer 140 or the variable resistance layer 160.

In some implementations, the layer structure of the memory cell MC can be modified in various manners without being limited to what is shown in FIG. 1. The stacking order of the layers of the memory cell MC may be changed, one or more of the layers of the memory cell MC may be omitted, or one or more additional layers may be added to the memory cell MC. As an example, one or more of the lower electrode layer 130, the middle electrode layer 150, and the upper electrode layer 170 may be omitted. Alternatively, the positions of the selector layer 140 and the variable resistance layer 160 may be reversed with each other. That is, the selector layer 140 may be located over the middle electrode layer 150, and the variable resistance layer 160 may be located under the middle electrode layer 150. Alternatively, one or more layers (not shown) may be added to the memory cell MC to improve the process or the characteristics of the memory cell MC.

In some implementations, there may be a restriction on the material and/or the thickness of the middle electrode layer 150 located between the selector layer 140 and the variable resistance layer 160, because of the difficulty of the patterning process, the diffusion of the dopant upon contact with the selector layer 140, or others. If there is the restriction on the material and/or the thickness of the middle electrode layer 150, it may be difficult to form the middle electrode layer 150 with desired characteristics, such as a desired bandwidth and/or a desired resistance. In addition, after forming the middle electrode layer 150, a process of forming an interlayer insulating layer to fill the space between the middle electrode layers 150 may be performed. In some implementation, a planarization process for the insulating material, such as etch-back or CMP (Chemical Mechanical Polishing), may be required. During this planarization process, the middle electrode layer 150 containing metal, etc. may protrude above the interlayer insulating layer, and thus, the upper surface of the middle electrode layer 150 and the upper surface of the interlayer insulating layer may form a non-flat surface. If the variable resistance layer 160 is formed over such a non-flat surface, the characteristics of the variable resistance layer 160 may deteriorate. For example, when the variable resistance layer 160 includes a magnetic tunnel junction structure in which a tunnel barrier layer is interposed between two magnetic layers, various problems may occur due to the non-flat surface formed by the middle electrode layer 150 and the interlayer insulating layer. For example, the crystal growth of the magnetic layer may not occur normally over the non-flat surface. Also, for example, the bending of the tunnel barrier layer may occur, which may cause a defect such as Neel coupling.

Hereinafter, a semiconductor device that can overcome the restriction on the middle electrode layer 150 and can form an interlayer insulating layer having an upper surface that is planarized with the upper surface of the middle electrode layer 150, and a method for fabricating the same, will be described.

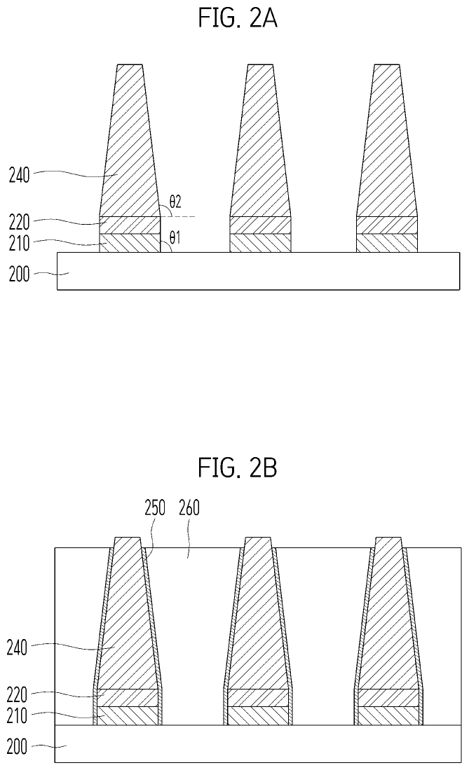

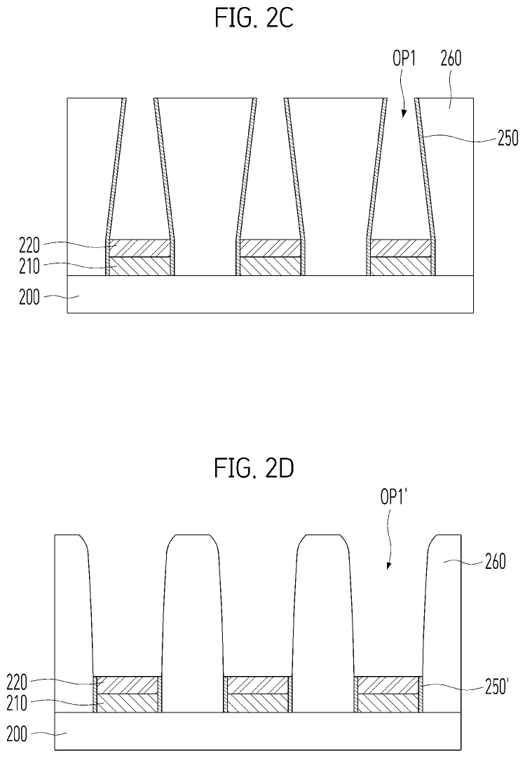

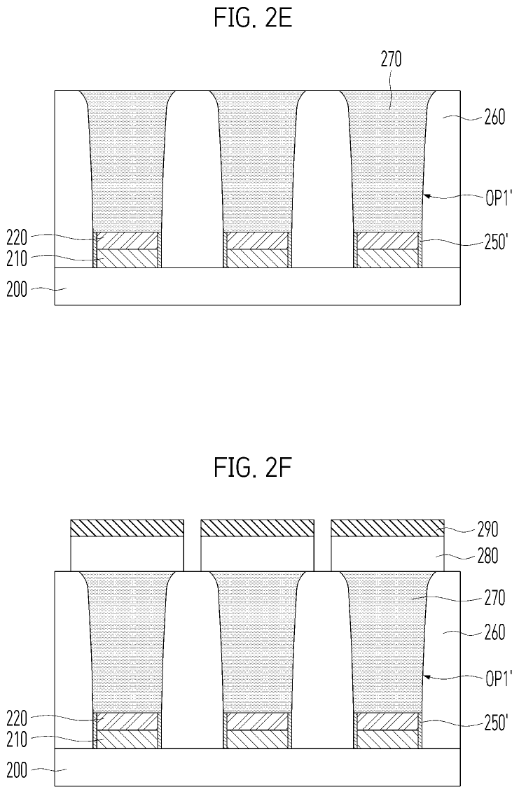

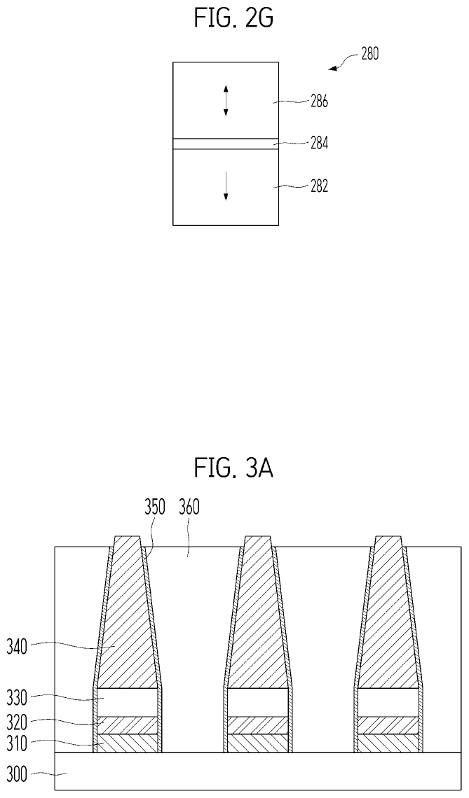

FIGS. 2A to 2F are cross-sectional views illustrating a semiconductor device according to an embodiment of the present disclosure, and a method for fabricating the same. Detailed description of parts that are substantially the same as the above-described embodiment will be omitted.

First, the fabricating method will be described.

Referring to FIG. 2A, a substrate 200 in which a predetermined lower structure is formed may be provided. The substrate 200 may include at least one of various circuits. For example, the substrate 200 may include a conductive line similar to the first conductive line 110 of FIG. 1 described above.

Subsequently, a stacked structure of a lower electrode 210, a selector pattern 220, and a sacrificial middle electrode 240 may be formed over the substrate 200. The stacked structure 210, 220, and 240 may be formed by sequentially forming a lower electrode material, a selector material, and a sacrificial electrode material over the substrate 200, and selectively etching them. The stacked structure 210, 220, and 240 may have a pillar shape. In the present embodiment, three stacked structures 210, 220, and 240 are shown to be spaced apart from each other, but the present disclosure is not limited thereto, and the number or the arrangement of the stacked structures 210, 220, and 240 may be modified in various ways.

The lower electrode 210 and the selector pattern 220 may be formed of or include the same material as the lower electrode layer 130 and the selector layer 140 of FIG. 1, respectively.

The sacrificial middle electrode 240 may include at least one of various materials that can be easily removed in a subsequent removal process. Furthermore, in the example, the thickness and the material of the sacrificial middle electrode 240 as described above may be commonly used in the art for the middle electrode. By designing the sacrificial middle electrode 240 to have the thickness and material which is used in the art can facilitate the etching process of forming the sacrificial middle electrode 240 since the thickness and material have already been appropriately adjusted in consideration of the difficulty of the patterning process. In an example, the sacrificial middle electrode 240 may include titanium nitride. In the example, because the sacrificial middle electrode 240 functions as an etch barrier together with a mask pattern (not shown) used during the etching process for forming the lower electrode 210 and the selector pattern 220, the sacrificial middle electrode 240 may be formed to have a thickness greater than a thickness of the lower electrode 210.

The sidewall slope of the sacrificial middle electrode 240 may be greater than the sidewall slope of each of the lower electrode 210 and the selector pattern 220. In the example, the angle θ1 formed by the sidewall of each of the lower electrode 210 and the selector pattern 220 with respect to the upper surface of the substrate 200 may be smaller than the angle θ2 formed by the sidewall of the sacrificial middle electrode 240 with respect to the upper surface of the substrate 200. The angle θ1 may be, for example, 90 degrees, and the angle θ2 may be, for example, an obtuse angle. Accordingly, the width of the sacrificial middle electrode 240 may increase from top to bottom, and the width of the uppermost portion of the sacrificial middle electrode 240 may be smaller than the width of the lower electrode 210 and/or the selector pattern 220. The sidewall slope of the sacrificial middle electrode 240 may be formed because the thickness of the sacrificial middle electrode 240 is much greater than the thickness of each of the lower electrode 210 and the selector pattern 220. In some implementations, the sidewall slope of the sacrificial middle electrode 240 may be formed by adjusting the process recipe. However, the present disclosure is not limited thereto, and the sidewall slope of the sacrificial middle electrode 240 may be substantially the same as the sidewall slope of the lower electrode 210 and/or the selector pattern 220.

Referring to FIG. 2B, an initial spacer 250 may be formed over the sidewall of the stacked structure including the lower electrode 210, the selector pattern 220, and the sacrificial middle electrode 240. The initial spacer 250 may have a function of protecting the selector pattern 220 during a subsequent forming process of an interlayer insulating layer 260. The initial spacer 250 may be conformally formed with a thin thickness while not completely filling the space between the stacked structures including the lower electrode 210, the selector pattern 220, and the sacrificial middle electrode 240. In the example, the initial spacer 250 may be formed along the sidewalls of the stacked structures including the lower electrode 210, the selector pattern 220, and the sacrificial middle electrode 240. For example, the initial spacer 250 may be formed by deposition of an insulating material such as silicon nitride. For example, the initial spacer 250 may be omitted. In this case, the interlayer insulating layer 260 may be in direct contact with the sidewall of the stacked structure including the lower electrode 210, the selector pattern 220, and the sacrificial middle electrode 240.

Subsequently, the interlayer insulating layer 260 may be formed to be filled between the stacked structures 210, 220, and 240. The interlayer insulating layer 260 may include an insulating material such as silicon oxide. In addition, the interlayer insulating layer 260 may be formed by depositing an insulating material thick enough to cover the stacked structures including the lower electrode 210, the selector pattern 220, and the sacrificial middle electrode 240 while sufficiently filling the space between the stacked structures, and performing a planarization process such as etch-back or CMP (Chemical Mechanical Polishing) on the insulating material until the upper surface of the sacrificial middle electrode 240 is exposed. During this planarization process, the interlayer insulating layer 260 may be lowered to a certain degree from the upper surface of the sacrificial middle electrode 240, and thus, the upper end of the sacrificial middle electrode 240 may protrude above the interlayer insulating layer 260. During this planarization process, the initial spacer 250 formed of and including an insulating material may also be lowered together with the interlayer insulating layer 260, and may have an upper surface located at substantially the same height as the upper surface of the interlayer insulating layer 260.

Referring to FIG. 2C, the sacrificial middle electrode 240 may be removed. The sacrificial middle electrode 240 may be removed using a suitable method, e.g., a wet dip-out method. When the sacrificial middle electrode 240 includes titanium nitride, the sacrificial middle electrode 240 may be removed by a dip-out method using hydrogen peroxide (H₂O₂). In this case, only the sacrificial middle electrode 240 may be selectively removed without causing substantial loss to the selector pattern 220, the initial spacer 250, and/or the interlayer insulating layer 260 that are located around the sacrificial middle electrode 240.

A space formed by removal of the sacrificial middle electrode 240 will hereinafter be referred to as an initial opening OP1. The initial opening OP1 may have a hollow shape such as a hole shape, and may have the narrowest width at the uppermost portion that corresponds to the entrance to the inside of the initial opening OP1. The initial opening OP1 may have a width that increases from top to bottom. The width of the entrance of the initial opening OP1 may be smaller than the width of the lower electrode 210 and/or the width of the selector pattern 220. The upper surface of the selector pattern 220 may be exposed by forming the initial opening OP1.

Referring to FIG. 2D, an opening OP1′ may be formed by expanding the width of the upper portion of the initial opening OP1.

The forming process of the opening OP1′ may be performed using a suitable method, e.g., a wet cleaning method. When the initial spacer 250 includes silicon nitride and the interlayer insulating layer 260 includes silicon oxide, the wet cleaning may be performed using a HF-based chemical. During this process, a portion of the initial spacer 250 exposed by the initial opening OP1 may be removed, and accordingly, a spacer 250′ surrounding the sidewalls of the lower electrode 210 and the selector pattern 220 may be formed. In addition, the interlayer insulating layer 260 exposed by the partial removal of the initial spacer 250 may also be partially removed. Since the exposure time of the initial opening OP1 to the chemical decreases from top to bottom, the removal amount of the interlayer insulating layer 260 may also decrease from top to bottom. As a result, the opening OP1′ may be formed that has the largest width at the uppermost portion. The opening OP1′ may have a width that decreases from top to bottom. In addition, the uppermost portion of the opening OP1′ may have a rounded edge in a cross-sectional view due to the influence of the wet chemical.

Referring to FIG. 2E, a middle electrode 270 filling the opening OP1′ may be formed.

The middle electrode 270 may be formed by depositing a conductive material with a thickness sufficient to fill the opening OP1′ over the process result of FIG. 2D, and performing a planarization process, such as CMP or etch-back, until the upper surface of the interlayer insulating layer 260 is exposed. The deposition of the conductive material for forming the middle electrode 270 may be performed using a method such as PVD (Physical Vapor Deposition) or ALD (Atomic Layer Deposition). In addition, the conductive material for forming the middle electrode 270 may include a metal such as iridium (Ir), platinum (Pt), tungsten (W), aluminum (Al), copper (Cu), tantalum (Ta), or titanium (Ti), a metal nitride such as titanium nitride (TIN), tantalum nitride (TaN), or tungsten nitride (WN), a non-metal such as polysilicon doped with impurities, or a combination thereof. The impurities may include carbon, boron, or others.

As a result of this process, the middle electrode 270 may be formed having the largest width at the uppermost portion and a decreasing width from top to bottom. In addition, the uppermost portion of the middle electrode 270 may have a rounded edge in a cross-sectional view.

During this process, since the opening OP1′ has the largest width at the uppermost portion and the width of the opening OP1′ decreases from top to bottom, the filling characteristic of the conductive material can be improved, which reduces and prevents the occurrence of defects such as a void formed within the middle electrode 270. In addition, unlike the process of FIG. 2B, since planarization is performed on the conductive material including metal, etc., the middle electrode 270 may have an upper surface that is substantially flat/planarized with the interlayer insulating layer 260. Thus, the upper surface of the middle electrode 270 and the upper surface of the interlayer insulating layer 260 may be positioned at substantially the same height in the vertical direction. This may be because, during etch-back or CMP, insulating materials are more likely to dent than metallic materials, while metallic materials are less prone to dent than insulating materials. Furthermore, since the width of the uppermost portion of the opening OP1′ is expanded, it may be more advantageous to flatten the upper surface of the middle electrode 270 that fills the opening OP1′ and the upper surface of the interlayer insulating layer 260.

Referring to FIG. 2F, a variable resistance pattern 280 and an upper electrode 290 may be formed over the process result of FIG. 2E.

The stacked structure of the variable resistance pattern 280 and the upper electrode 290 may contact the middle electrode 270 to be electrically connected to the middle electrode 270. The variable resistance pattern 280 and the upper electrode 290 may be formed by depositing a material for forming the variable resistance pattern 280 and a conductive material for forming the upper electrode 290 over the process result of FIG. 2E, and selectively etching them. Since the variable resistance pattern 280 and the upper electrode 290 are patterned using another mask different from a mask used to form the lower electrode 210, the selector pattern 220, and the middle electrode 270, the sidewalls of the variable resistance pattern 280 and the upper electrode 290 may not be aligned with the sidewalls of the lower electrode 210, the selector pattern 220, and the middle electrode 270.

In the present embodiment, the variable resistance pattern 280 is formed over the selector pattern 220, but the present disclosure is not limited thereto. In another embodiment, the variable resistance pattern 280 may be formed under the lower electrode 210, before forming the lower electrode 210. Therefore, the variable resistance pattern 280 may be formed under the selector pattern 220. Even in this case, the variable resistance pattern 280 may be electrically connected to the selector pattern 220 through the lower electrode 210.

In an example, the variable resistance pattern 280 may include a magnetic tunnel junction structure, which will be described with reference to FIG. 2G.

FIG. 2G is a cross-sectional view illustrating an example of a variable resistance pattern.

Referring to FIG. 2G, the variable resistance pattern 280 may be a magnetic tunnel junction structure, and may include a pinned layer 282, a tunnel barrier layer 284, and a free layer 286.

The pinned layer 282 may be a layer that has a fixed magnetization direction that can be compared to the magnetization direction of the free layer 286, and may also be called a reference layer. The free layer 286 may be a layer that can store different data by having a changeable magnetization direction, and may also be called a storage layer. The tunnel barrier layer 284 may physically separate the pinned layer 282 and the free layer 286, and may enable tunneling of electrons between them. Each of the pinned layer 282 and the free layer 286 may have a single-layer structure or multi-layer structure including a ferromagnetic material. As an example, each of the pinned layer 282 and the free layer 286 may include an alloy containing Fe, Ni, or Co as a main component, such as Fe—Pt alloy, Fe—Pd alloy, Co—Pd alloy, Co—Pt alloy, Fe—Ni—Pt alloy, Co—Fe—Pt alloy, Co—Ni—Pt alloy, or Co—Fe—B alloy, or, at least one of stacked structures of Co/Pt and Co/Pd. The tunnel barrier layer 284 may have a single-layer structure or multi-layer structure including an insulating material. As an example, the tunnel barrier layer 284 may include an insulating oxide such as MgO, CaO, SrO, TiO, VO, or NbO.

In this magnetic tunnel junction structure, the magnetization direction of the free layer 286 may vary depending on the applied voltage or current. When the magnetization direction of the free layer 286 is parallel to the magnetization direction of the pinned layer 282, the magnetic tunnel junction structure may have a low resistance state and, for example, may store data ‘1’. On the other hand, when the magnetization direction of the free layer 286 is anti-parallel to the magnetization direction of the pinned layer 282, the magnetic tunnel junction structure may have a high resistance state and, for example, may store data ‘0’.

As long as the magnetic tunnel junction structure includes the pinned layer 282, the free layer 286, and the tunnel barrier layer 284 therebetween, the layer structure of the magnetic tunnel junction structure may be modified in various ways. For example, the positions of the pinned layer 282 and the free layer 286 may be reversed with each other. In an example, although not shown, one or more layers to improve the characteristics of the magnetic tunnel junction structure may be further added to the magnetic tunnel junction structure.

It may be important for this magnetic tunnel junction structure to be formed on a flat surface, that is, a planarized surface. This may be because, if the magnetic tunnel junction structure is not formed on a flat surface, crystal growth of a magnetic material is difficult and a defect of bending of a tunnel barrier layer occurs, thereby deteriorating the switching characteristic of the magnetic tunnel junction structure.

Referring again to FIG. 2F, when the variable resistance pattern 280 includes a magnetic tunnel junction structure, the variable resistance pattern 280 may be located on the upper surface of the middle electrode 270 and the upper surface of the interlayer insulating layer 260 that form a substantially flat surface. Therefore, deterioration of the characteristics of the variable resistance pattern 280 may be prevented and/or reduced.

The semiconductor device may be fabricated using the above-described method.

Referring again to FIG. 2F, the semiconductor device of the present embodiment may include the substrate 200, the stacked structure including the lower electrode 210, the selector pattern 220, and the middle electrode 270 and disposed over the substrate 200, the interlayer insulating layer 260 that fills the space between the stacked structures 210, 220, and 270, the spacer 250′ disposed between the interlayer insulating layer 260 and the lower electrode 210 and between the interlayer insulating layer 260 and the selector pattern 220, and the variable resistance pattern 280 and the upper electrode 290 formed over the middle electrode 270 and the interlayer insulating layer 260.

Here, the interlayer insulating layer 260 may be in direct contact with the sidewall of the middle electrode 270, and the upper surface of the interlayer insulating layer 260 and the upper surface of the middle electrode 270 may form a flat surface. The width of the middle electrode 270 may be maximum at the uppermost portion, that is, at the upper surface. In addition, the middle electrode 270 may have a width that decreases from top to bottom. The uppermost portion of the middle electrode 270 may have a rounded edge in a cross-sectional view.

A more detailed description of the components of the semiconductor device of the present embodiment has already been described in the process of explaining the fabricating method, so it will be omitted here.

According to the semiconductor device and its fabricating method described above, since the middle electrode 270 is formed without using an etching process, the middle electrode 270 may not be limited by the etching process. Accordingly, various desired materials may be used as the middle electrode 270.

Additionally, Since the middle electrode 270 is formed in the opening OP1′ having an expanded uppermost portion, the filling characteristic of the conductive material for forming the middle electrode 270 may be improved, and thus, filling defects may be reduced and/or prevented.

Furthermore, since the planarization process is performed on the conductive material for forming the middle electrode 270, it may be possible to easily form a flat surface formed by the upper surface of the middle electrode 270 and the upper surface of the interlayer insulating layer 260. In particular, since the middle electrode 270 is formed in the opening OP1′ having an expanded uppermost portion, the forming of the flat surface may be more advantageous. As a result, the variable resistance pattern 280 may be located on the flat surface, and accordingly, it may be possible to secure the characteristics of the variable resistance pattern 280, for example, a magnetic tunnel junction structure.

As a result, it may be possible to secure the required characteristics of the memory cell and prevent and/or reduce the occurrence of the defects.

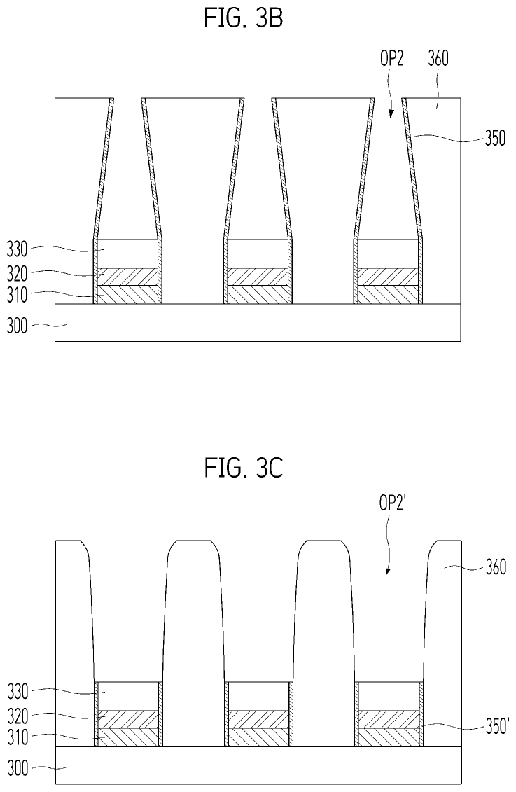

FIGS. 3A to 3C are cross-sectional views illustrating a semiconductor device according to another embodiment of the present disclosure, and a method for fabricating the same. The description will focus on differences from the above-described embodiments.

Referring to FIG. 3A, a stacked structure of a lower electrode 310, a selector pattern 320, a buffer pattern 330, and a sacrificial middle electrode 340 may be formed over a substrate 300 in which a predetermined lower structure is formed.

Here, the buffer pattern 330 may serve to protect the selector pattern 320 when the sacrificial middle electrode 340 is removed later. In the implementation, the buffer pattern 330 may include a material having an etch rate different from that of the sacrificial middle electrode 340 during a wet dip-out process for removal of the sacrificial middle electrode 340. In the present embodiment, since the buffer pattern 330 is not removed but is interposed between a middle electrode to be described later and the selector pattern 320, the buffer pattern 330 may have a conductive property for electrical connection between the middle electrode and the selector pattern 320. In addition, the buffer pattern 330 may include a material with a relatively high resistivity. For example, the buffer pattern 330 may include a material having a greater resistivity than a material for forming the middle electrode. In this case, the buffer pattern 330 may function as a kind of resistance layer that reduces a hold current of the selector pattern 320. As an example, the buffer pattern 330 may include amorphous carbon. However, the present disclosure is not limited thereto, and the material for forming the buffer pattern 330 may be variously modified as long as the buffer pattern 330 includes a material having a different etch rate from the selector pattern 320.

Next, an initial spacer 350 may be formed over the sidewall of the stacked structure 310, 320, 330, and 340, and then, an interlayer insulating layer 360 may be formed to fill the space between the stacked structures 310, 320, 330, and 340.

Referring to FIG. 3B, an initial opening OP2 may be formed by removing the sacrificial middle electrode 340. The sacrificial middle electrode 340 may be removed using a wet dip-out method. When the sacrificial middle electrode 340 is removed, the buffer pattern 330 may cover the upper surface of the selector pattern 320, so the selector pattern 320 may not be exposed to a chemical used in the wet dip-out process and may be protected. Accordingly, when using the buffer pattern 330, it may be advantageous to secure the characteristics of the selector pattern 320.

Referring to FIG. 3C, an opening OP2′ may be formed by expanding the width of the upper portion of the initial opening OP2. The forming process of the opening OP2′ may be performed using a wet cleaning method. During this wet cleaning process, the buffer pattern 330 may cover the upper surface of the selector pattern 320, so the selector pattern 320 may not exposed to a chemical used during the wet cleaning and may be protected. Accordingly, it may be more advantageous to secure the characteristics of the selector pattern 320.

The opening OP2′ may have the largest width at the uppermost portion, and may have a shape where the width decreases from top to bottom. In addition, the uppermost portion of the opening OP2′ may have a rounded edge in a cross-sectional view.

During the forming of the opening OP2′, a portion of the initial spacer 350 may be removed, and a spacer 350′ disposed between the sidewalls of the lower electrode 310, the selector pattern 320, and the buffer pattern 330 and the interlayer insulating layer 360 may be formed.

Next, although not shown, a subsequent process such as a forming process of a middle electrode filled in the opening OP2′ may be performed.

According to the present embodiment, all the advantages of the above-described embodiments may be obtained. In addition, by forming the buffer pattern 330 to cover the selector pattern 320, there may be an advantage of protecting the selector pattern 320 during the forming of the initial opening OP2 and the forming of the opening OP2′. Furthermore, by adjusting the resistance of the buffer pattern 330, the characteristics of the selector pattern 320, such as hold current, may be adjusted more precisely.

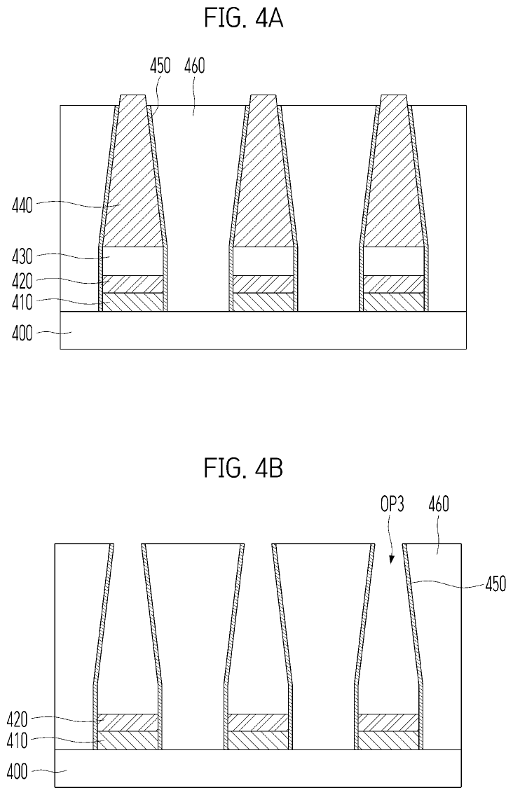

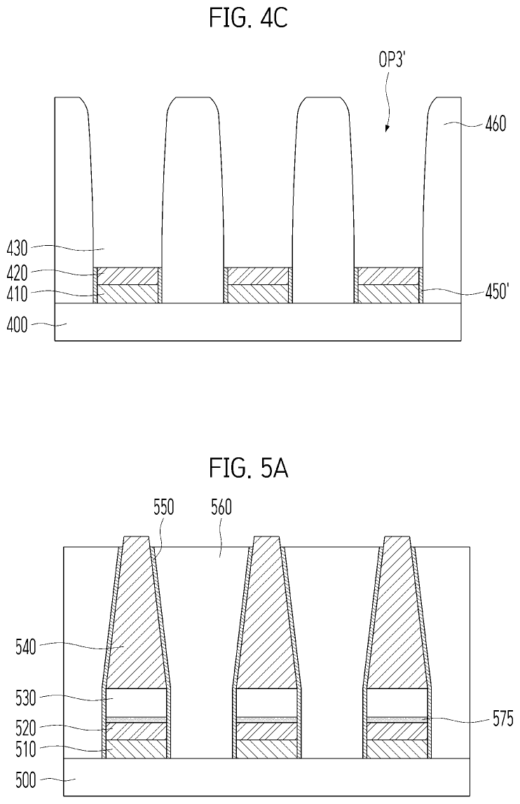

FIGS. 4A to 4C are cross-sectional views illustrating a semiconductor device according to another embodiment of the present disclosure, and a method for fabricating the same. The description will focus on differences from the above-described embodiments.

Referring to FIG. 4A, a stacked structure of a lower electrode 410, a selector pattern 420, a buffer pattern 430, and a sacrificial middle electrode 440 may be formed over a substrate 400 in which a predetermined lower structure is formed.

Here, the buffer pattern 430 may serve to protect the selector pattern 420 when the sacrificial middle electrode 440 is removed later. To this end, the buffer pattern 430 may include a material having an etch rate different from that of the sacrificial middle electrode 440 during a wet dip-out process for removal of the sacrificial middle electrode 440. Since the buffer pattern 430 is to be removed in the present embodiment, the buffer pattern 430 may not need to have a conductive property, and may use at least one of various materials such as a conductive material or an insulating material. The buffer pattern 430 may have a material that can be easily removed.

Next, a spacer 450 may be formed over the sidewall of the stacked structure 410, 420, 430, and 440, and then, an interlayer insulating layer 460 may be formed to fill the space between the stacked structures 410, 420, 430, and 440.

Referring to FIG. 4B, the sacrificial middle electrode 440 may be removed, and then, the buffer pattern 430 exposed by removal of the sacrificial middle electrode 440 may be removed, thereby forming an initial opening OP3. The sacrificial middle electrode 440 may be removed using a wet dip-out method. The buffer pattern 430 may be removed through at least one of various removal methods. When the buffer pattern 430 includes carbon, the buffer pattern 430 may be removed through a strip process containing oxygen.

Referring to FIG. 4C, an opening OP3′ may be formed by expanding the width of the upper portion of the initial opening OP3. The forming process of the opening OP3′ may be performed using a wet cleaning method.

The opening OP3′ may have the largest width at the uppermost portion, and may have a shape where the width decreases from top to bottom. In addition, the uppermost portion of the opening OP3′ may have a rounded edge in a cross-sectional view.

During the forming of the opening OP3′, a portion of the initial spacer 450 may be removed, and a spacer 450′ disposed between the sidewall of the lower electrode 410 and the interlayer insulating layer 460 and between the sidewall of the selector pattern 420 and the interlayer insulating layer 460 may be formed.

According to the present embodiment, all the advantages of the above-described embodiments may be obtained. In addition, by forming the buffer pattern 430 to cover the selector pattern 420, there may be an advantage of protecting the selector pattern 420 during the removal of the sacrificial middle electrode 440.

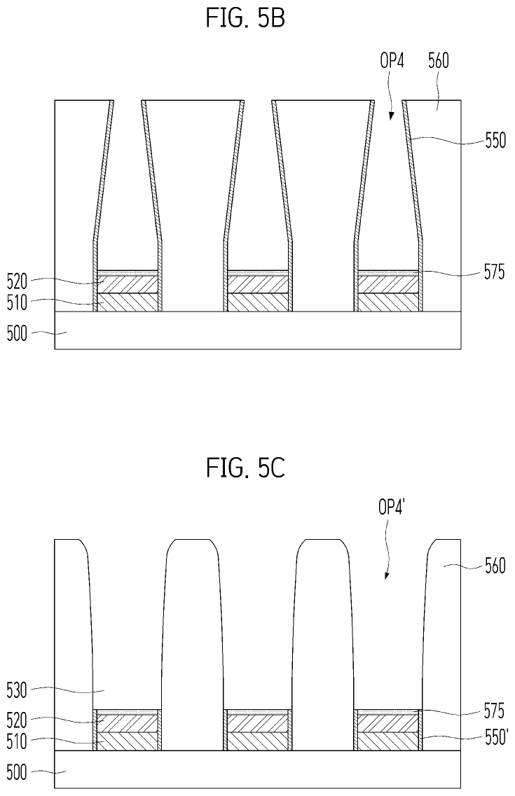

FIGS. 5A to 5C are cross-sectional views illustrating a semiconductor device according to another embodiment of the present disclosure, and a method for fabricating the same. The description will focus on differences from the above-described embodiments.

Referring to FIG. 5A, a stacked structure of a lower electrode 510, a selector pattern 520, an additional electrode 575, a buffer pattern 530, and a sacrificial middle electrode 540 may be formed over a substrate 500 in which a predetermined lower structure is formed.

Here, the additional electrode 575 may serve to protect the selector pattern 520 when the buffer pattern 530 is removed later, and may serve as an electrode located over the selector pattern 520, together with a middle electrode to be described later. The additional electrode 575 may include substantially the same material as the middle electrode.

Subsequently, an initial spacer 550 may be formed over the sidewall of the stacked structure 510, 520, 575, 530, and 540, and then, an interlayer insulating layer 560 may be formed to fill the space between the stacked structures 510, 520, 575, 530, and 540.

Referring to FIG. 5B, the sacrificial middle electrode 540 may be removed, and then, the buffer pattern 530 exposed by removal of the sacrificial middle electrode 540 may be removed, thereby forming an initial opening OP4. When the buffer pattern 530 is removed, the additional electrode 575 may protect the selector pattern 520.

Referring to FIG. 5C, an opening OP4′ may be formed by expanding the width of the upper portion of the initial opening OP4. The forming process of the opening OP4′ may be performed using a wet cleaning method. During this wet cleaning process, the additional electrode 575 may protect the selector pattern 520.

The opening OP4′ may have the largest width at the uppermost portion, and may have a shape where the width decreases from top to bottom. Thus, the opening OP4′ may have a tapering shape that has a maximum width at the top of the opening OP4′. In addition, the uppermost portion of the opening OP4′ may have a rounded edge in a cross-sectional view. The rounded edge of the uppermost portion of the opening OP4′ may refer to the edge having a curved shape.

During the forming of the opening OP4′, a portion of the initial spacer 550 may be removed, and a spacer 550′ disposed between the sidewalls of the lower electrode 510, the selector pattern 520, and the additional electrode 575 and the interlayer insulating layer 560 may be formed.

According to the present embodiment, the advantages of the above-described embodiments may be obtained. In addition, by forming the buffer pattern 530 to cover the selector pattern 520, there may be an advantage of protecting the selector pattern 520 during the removal of the sacrificial middle electrode 540. In addition, by interposing the additional electrode 575 between the buffer pattern 530 and the selector pattern 520, there may be an advantage of protecting the selector pattern 520 when the buffer pattern 530 is removed and a subsequent cleaning process is performed. Since the additional electrode 575 performs an electrode function together with the middle electrode, a separate removal process of the additional electrode 575 may not be required.

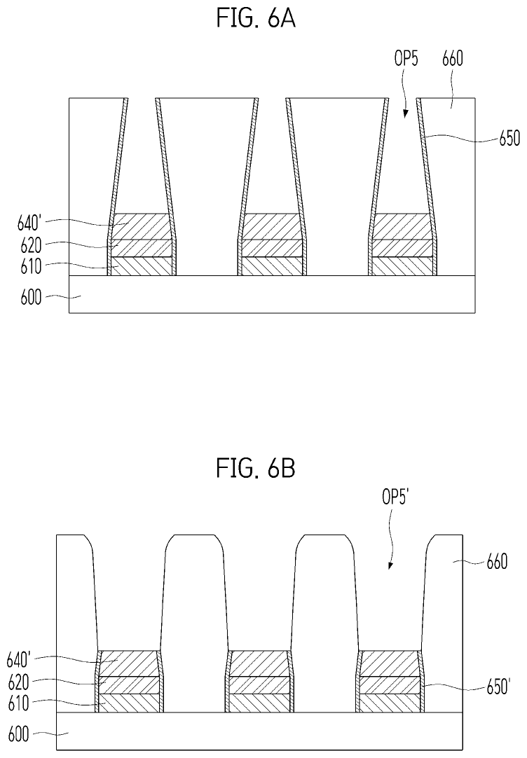

FIGS. 6A and 6B are cross-sectional views illustrating a semiconductor device according to another embodiment of the present disclosure, and a method for fabricating the same. The description will focus on differences from the above-described embodiments.

Referring to FIG. 6A, by performing substantially the same process as the process of FIGS. 2A and 2B, a stacked structure of a lower electrode 610, a selector pattern 620, and a sacrificial middle electrode, a spacer 650 formed over the sidewall of the stacked structure of the lower electrode 610, the selector pattern 620, and the sacrificial middle electrode, and an interlayer insulating layer 660 may be formed.

Next, the sacrificial middle electrode may be removed, but unlike the above-described embodiment, only a portion of the sacrificial middle electrode may be removed, so that a lower portion of the sacrificial middle electrode may remain over the selector pattern 620. The partial removal of the sacrificial middle electrode may be possible by adjusting the time of the wet dip out process. The lower portion of the sacrificial middle electrode, which remains over the selector pattern 620, will hereinafter be referred to as a sacrificial middle electrode pattern 640′. In addition, the space formed by forming the sacrificial middle electrode pattern 640′ will hereinafter be referred to as an initial opening OP5. The sacrificial middle electrode pattern 640′ may serve to protect the selector pattern 620 during a cleaning process to be described later. In addition, the sacrificial middle electrode pattern 640′ may function as an electrode located over the selector pattern 620 together with the middle electrode.

Referring to FIG. 6B, an opening OP5′ may be formed by expanding the width of the upper portion of the initial opening OP5. The forming process of the opening OP5′ may be performed using a wet cleaning method. During this wet cleaning process, the sacrificial middle electrode pattern 640′ may protect the selector pattern 620.

The opening OP5′ may have the largest width at the uppermost portion, and may have a shape where the width decreases from top to bottom. Thus, the opening OP5′ may have a tapering shape that has a maximum width at the top of the opening OP5′. In addition, the uppermost portion of the opening OP5′ may have a rounded edge in a cross-sectional view. The rounded edge of the uppermost portion of the opening OP5′ may refer to the edge having a curved shape.

During the forming of the opening OP5′, a portion of the initial spacer 650 may be removed, and a spacer 650′ disposed between the sidewalls of the lower electrode 610, the selector pattern 620, and the sacrificial middle electrode pattern 640′ and the interlayer insulating layer 660 may be formed.

According to the present embodiment, the advantages of the above-described embodiments can be obtained. In addition, by forming the sacrificial middle electrode pattern 640′ to cover the selector pattern 620, it is possible to protecting the selector pattern 620 during the cleaning process. The sacrificial middle electrode pattern 640′ may include the same material as the middle electrode to be filled in the opening OP5′, or may include a different material from the middle electrode.

According to the above embodiments of the present disclosure, it may be possible to secure the characteristics of the memory cell and reducing and/or preventing occurrence of defects.

While the disclosed technology has been illustrated and described with respect to specific embodiment, it should be understood that various enhancements and modifications of the disclosed embodiments and other embodiments may be made based on what is described and illustrated in this patent document.

What is claimed is:

1. A semiconductor device comprising:
a selector pattern configured to exhibit different electrical conducting characteristics in response to an applied voltage with respect to a threshold voltage;
an interlayer insulating layer surrounding a sidewall of the selector pattern and having an opening disposed over the selector pattern; and
an electrode disposed in the opening and having a width that is maximum at an uppermost portion of the opening, and
wherein the uppermost portion of the opening has a rounded edge in a cross-sectional view.

2. The semiconductor device according to claim 1, wherein the width of the opening decreases from the uppermost portion to a bottom of the opening.

3. The semiconductor device according to claim 1, further comprising:
a spacer disposed between the sidewall of the selector pattern and the interlayer insulating layer.

4. The semiconductor device according to claim 1, further comprising:
a buffer pattern disposed between the selector pattern and the electrode.

5. The semiconductor device according to claim 4, wherein the buffer pattern includes a material having a higher resistivity than the electrode.

6. The semiconductor device according to claim 4, wherein the buffer pattern includes amorphous carbon.

7. The semiconductor device according to claim 4, further comprising:
a spacer disposed between the sidewall of the selector pattern and the interlayer insulating layer and between a sidewall of the buffer pattern and the interlayer insulating layer.

8. The semiconductor device according to claim 1, further comprising:
an additional electrode disposed between the selector pattern and the electrode.

9. The semiconductor device according to claim 8, further comprising:
a spacer disposed between the sidewall of the selector pattern and the interlayer insulating layer and between a sidewall of the additional electrode and the interlayer insulating layer.

10. The semiconductor device according to claim 1, wherein the electrode and the interlayer insulating layer have planarized upper surfaces.

11. The semiconductor device according to claim 10, further comprising:
a magnetic tunnel junction structure formed over the planarized upper surfaces and electrically connected to the electrode.

12. A method for fabricating a semiconductor device, comprising:
providing a stacked structure in which a selector pattern and a sacrificial electrode are stacked to each other, wherein the selector pattern is configured to exhibit different electrical conducting characteristics in response to an applied voltage with respect to a threshold voltage;
forming an interlayer insulating layer surrounding a sidewall of the stacked structure;
removing the sacrificial electrode to form an initial opening;
expanding a width of an uppermost portion of the initial opening to form an opening; and
forming an electrode filled in the opening.

13. The method according to claim 12, wherein the forming of the opening is performed using wet cleaning.

14. The method according to claim 12, wherein the sacrificial electrode includes titanium nitride, and
the sacrificial electrode is removed using hydrogen peroxide.

15. The method according to claim 12, wherein the forming of the electrode comprises:
depositing a conductive material over the interlayer insulating layer to fill the opening; and
performing a planarization process to expose an upper surface of the interlayer insulating layer.

16. The method according to claim 15, wherein the electrode has an upper surface that is planarized with the upper surface of the interlayer insulating layer, and
the method further comprises:
forming a magnetic tunnel junction structure over the upper surface of the interlayer insulating layer and the upper surface of the electrode to be electrically connected to the electrode, after the forming of the electrode.

17. The method according to claim 12, further comprising:
forming a spacer over the sidewall of the stacked structure, before the forming of the interlayer insulating layer, and
wherein, in the forming of the opening, a portion of the spacer exposed by the initial opening is removed.

18. The method according to claim 12, wherein the stacked structure further includes a buffer pattern disposed between the sacrificial electrode and the selector pattern.

19. The method according to claim 18, wherein, in the forming of the initial opening, the buffer pattern is maintained.

20. The method according to claim 18, wherein, in the forming of the initial opening, the buffer pattern is further removed.

21. The method according to claim 18, wherein the stacked structure further includes an additional electrode disposed between the buffer pattern and the selector pattern, and
in the forming of the initial opening, the additional electrode is maintained.

22. The method according to claim 12, wherein, in the forming of the initial opening, a portion of the sacrificial electrode remains to be located over the selector pattern.
